(19) United States
(12) Patent Application Publication
(10) Pub. No.: US 2025/0366328 A1
(43) Pub. Date: Nov. 27, 2025

(54) DISPLAY DEVICE AND ELECTRONIC DEVICE HAVING THE SAME

(71) Applicant: Samsung Display Co., Ltd., Yongin-si (KR)

(72) Inventors: SUNKWUN SON, Yongin-si (KR); DONG HEE SHIN, Yongin-si (KR)

(21) Appl. No.: 19/094,602

(22) Filed: Mar. 28, 2025

(30) Foreign Application Priority Data
May 21, 2024 (KR) 10-2024-0066032

(51) Int. Cl. H10K 59/131; G09G 3/3233; H10K 59/35; H10K 59/95

(52) U.S. Cl. CPC H10K 59/131; H10K 59/95; G09G 3/3233; G09G 2300/0819; G09G 2300/0842; G09G 2300/0861; G09G 2320/0238; G09G 2360/14; H10K 59/35

(57) ABSTRACT

A display device includes: a base layer including display and a non-display areas, the display area including unit areas arranged in a first direction, and the non-display area includes a chip area and a pad area farther away from the display area than the chip area; a driver IC in the chip area; a pixel corresponding to each of the unit areas; an optical sensor corresponding to each of the unit areas; and signal line groups corresponding to the unit areas, respectively, wherein the signal line groups include: a data line extending from the chip area to the display area and electrically connect the pixel to the driver IC; and a readout line extending from the pad area to the display area and overlapping the chip area and electrically connected to the optical sensor, and wherein the data line and the readout line do not overlap each other.

### CROSS-REFERENCE TO RELATED APPLICATION

The present application claims priority to and the benefit of Korean Patent Application No. 10-2024-0066032, filed on May 21, 2024, in the Korean Intellectual Property Office, the entire disclosure of which is incorporated herein by reference.

### BACKGROUND

Aspects of some embodiments of the present disclosure described herein relate to a display device.

Electronic devices, such as smart phones, digital cameras, notebook computers, car navigation units, smart televisions, and the like, which provide or display images to users include a display device for displaying images. The display device includes a display panel for generating images, an input device such as an input sensor, a camera for taking an external image, and various sensors.

The input sensor is on the display panel and senses a touch of the user. The sensors may include a fingerprint sensor, a proximity sensor, and an illuminance sensor. Among the sensors, the fingerprint sensor senses the user's fingerprint provided on the display panel.

The above information disclosed in this Background section is only for enhancement of understanding of the background and therefore the information discussed in this Background section does not necessarily constitute prior art.

### SUMMARY

Aspects of some embodiments of the present disclosure described herein relate to a display device, and for example, relate to a display device including an optical sensor and an electronic device having the display device.

Aspects of some embodiments of the present disclosure include a display device including optical sensors arranged throughout a display surface.

Aspects of some embodiments of the present disclosure include an electronic device having the display device.

According to some embodiments of the present disclosure, a display device includes a base layer including a display area including a plurality of unit areas arranged in a first direction and a non-display area including a chip area and a pad area located farther away from the display area in a second direction crossing the first direction than the chip area, a driver IC in the chip area, a pixel that corresponds to each of the plurality of unit areas, an optical sensor that corresponds to each of the plurality of unit areas, and signal line groups that correspond to the plurality of unit areas, respectively, and that are arranged in the first direction. According to some embodiments, each of the signal line groups includes a data line that extends from the chip area to the display area in the second direction and electrically connects the pixel to the driver IC and a readout line that extends from the pad area to the display area in the second direction and overlaps the chip area and that is electrically connected to the optical sensor. According to some embodiments, the data line and the readout line do not overlap each other in the non-display area.

According to some embodiments, the plurality of unit areas may define a unit row, and among the unit areas in the unit row, a first unit area may be at one end of the display area in the first direction, and a last unit area may be at an opposite end of the display area in the first direction.

According to some embodiments, the data line and the readout line may be on the same layer in the non-display area.

According to some embodiments, each of the data line and the readout line may include a first portion and a second portion on a layer different from a layer on which the first portion is located.

According to some embodiments, the pixel may include a first pixel and a second pixel that generate light of different colors. According to some embodiments, the data line may include a first data line electrically connected to the first pixel and a second data line electrically connected to the second pixel. In a partial area of the non-display area located between the chip area and the display area, the first data line, the second data line, and the readout line may be continuously arranged in the first direction, the first data line and the readout line may be on a first insulating layer, and the second data line may be on a second insulating layer different from the first insulating layer.

According to some embodiments, the pixel may include a first pixel, a second pixel, a third pixel, and a fourth pixel, and the optical sensor may include a first optical sensor and a second optical sensor. According to some embodiments, the data line may include a first data line electrically connected to the first pixel, a second data line electrically connected to the second pixel, a third data line electrically connected to the third pixel, and a fourth data line electrically connected to the fourth pixel. According to some embodiments, the readout line may include a first readout line electrically connected to the first optical sensor and a second readout line electrically connected to the second optical sensor. In a partial area of the non-display area located between the chip area and the display area, the first data line, the second data line, and the first readout line may be continuously arranged in the first direction, the first data line and the first readout line may be on a first insulating layer, and the second data line may be on a second insulating layer different from the first insulating layer.

According to some embodiments, in the partial area of the non-display area, the third data line, the fourth data line, and the second readout line may be continuously arranged in the first direction from the second data line, the third data line and the second readout line may be on the second insulating layer, and the fourth data line may be on the first insulating layer.

According to some embodiments, the pixel may include a dummy electrode, a first transistor, a second transistor, and a light emitting element electrically connected to at least one of the first transistor or the second transistor. According to some embodiments, the first transistor may include a silicon semiconductor layer and a first gate electrode arranged over the silicon semiconductor layer. According to some embodiments, the second transistor may include an oxide semiconductor layer above the first gate electrode and a second gate electrode over the oxide semiconductor layer. According to some embodiments, the dummy electrode may be between the first gate electrode and the second gate electrode. According to some embodiments, in the partial area of the non-display area, the first data line and the first readout line may be on the same layer as one of the first gate electrode, the dummy electrode, and the second gate electrode.

According to some embodiments, in the partial area of the non-display area, the second data line may be on the same layer as another one of the first gate electrode, the dummy electrode, and the second gate electrode.

According to some embodiments, the display device may further include a power line that is electrically connected to the pixel and the optical sensor and that receives a driving voltage, and the power line may not overlap the data line and the readout line in a partial area of the non-display area located between the chip area and the display area.

According to some embodiments, the pixel may include a first pixel and a second pixel that generate light of different colors. The data line may include a first data line electrically connected to the first pixel and a second data line electrically connected to the second pixel. In the partial area of the non-display area, the first data line, the second data line, the power line, and the readout line may be continuously arranged in the first direction.

According to some embodiments, the first data line and the power line may be on a first insulating layer, and the second data line and the readout line may be on a second insulating layer different from the first insulating layer.

According to some embodiments, the power line may include at least one first portion that extends from the pad area in the second direction, a second portion that is connected to the at least one first portion and that extends in the first direction, and third portions that are connected to the second portion and that extend in the second direction to overlap the display area and correspond to the signal line groups, respectively.

According to some embodiments, the second portion may be on a layer different from layers on which the first data line, the second data line, and the readout line are located.

According to some embodiments of the present disclosure, an electronic device comprises a display device. According to some embodiments, the display device includes a base layer including a display area and a non-display area arranged around the display area, a driver IC in the non-display area, first to fourth pixels in the display area, a first optical sensor and a second optical sensor in the display area, and signal lines that overlap the display area and the non-display area, and a printed circuit board coupled to the non-display area of the base layer. According to some embodiments, the signal lines include first to fourth data lines that electrically connect the first to fourth pixels to the driver IC and a first readout line and a second readout line that electrically connect the first optical sensor and the second optical sensor to the printed circuit board. According to some embodiments, the first to fourth data lines do not overlap the first readout line and the second readout line at least in the non-display area. According to some embodiments, end portions of the first to fourth data lines overlap the driver IC, and middle portions of the first readout line and the second readout line overlap the driver IC.

According to some embodiments, in a partial area of the non-display area located between the driver IC and the display area, the first data line, the second data line, and the first readout line may be continuously arranged in a first direction, the first data line and the first readout line may be on a first insulating layer, and the second data line may be on a second insulating layer different from the first insulating layer.

According to some embodiments, in the partial area of the non-display area, the third data line, the fourth data line, and the second readout line may be continuously arranged in the first direction from the second data line, the third data line and the second readout line may be on the second insulating layer, and the fourth data line may be on the first insulating layer.

According to some embodiments, the display device may further include a power line that is electrically connected to the first to fourth pixels, the first optical sensor, and the second optical sensor and that receives a driving voltage. According to some embodiments, in a partial area of the non-display area located between the driver IC and the display area, the power line may be between a corresponding one of the first to fourth data lines and a corresponding one of the first readout line and the second readout line.

According to some embodiments, among the first to fourth data lines, the first readout line, and the second readout line, adjacent signal lines may be on different layers in the partial area of the non-display area.

According to some embodiments of the present disclosure, an electronic device comprises a display device. According to some embodiments, the display device includes a base layer including a display area in which a plurality of pixels and a plurality of optical sensors are located and a non-display area arranged around the display area, a driver IC in the non-display area, a printed circuit board coupled to the non-display area of the base layer, a first signal line that extends from an area overlapping the driver IC to the display area and electrically connects the driver IC and a first pixel among the plurality of pixels, and a second signal line that extends from an area overlapping the printed circuit board to the display area through an area overlapping the driver IC and electrically connects the printed circuit board and a first optical sensor among the plurality of optical sensors. According to some embodiments, among the plurality of pixels and the plurality of optical sensors, the first pixel and the first optical sensor are located closest to each other, and another signal line that extends in a direction parallel to the first signal line or the second signal line is not between the first signal line and the second signal line.

### BRIEF DESCRIPTION OF THE DRAWINGS

The above and other aspects and features of some embodiments of the present disclosure will become more apparent by describing in more detail aspects of some embodiments thereof with reference to the accompanying drawings.

FIG. 1 is a perspective view of a display device according to some embodiments of the present disclosure.

FIG. 2 is a sectional view of the display device illustrated in FIG. 1.

FIG. 3 is a sectional view of a display panel illustrated in FIG. 2.

FIG. 4 is a block diagram of the display device according to some embodiments of the present disclosure.

FIG. 5 is a view illustrating an equivalent circuit of one pixel among pixels illustrated in FIG. 4 and an optical sensor adjacent to the one pixel.

FIG. 6 is a sectional view illustrating a light emitting element, a first transistor, a fourth transistor, and a sixth transistor of the pixel illustrated in FIG. 5.

FIG. 7 is a sectional view illustrating a light sensing element, a first sensing transistor, and a second sensing transistor of the optical sensor illustrated in FIG. 5.

FIG. 8 is a view illustrating a planar arrangement of light emitting elements and light sensing elements located in a partial area of a display area illustrated in FIG. 4.

FIG. 9 is a plan view illustrating the display device according to some embodiments of the present disclosure.

FIG. 10 is an enlarged plan view illustrating a data line and a readout line according to some embodiments of the present disclosure.

FIG. 11A is an enlarged plan view illustrating a first area of a non-display area in FIG. 9.

FIG. 11B is an enlarged plan view illustrating a second area of the non-display area in FIG. 9.

FIG. 11C is an enlarged plan view illustrating a third area of the non-display area in FIG. 9.

FIG. 12 is an enlarged plan view illustrating the non-display area of the display device according to some embodiments of the present disclosure.

FIG. 13 is an enlarged plan view illustrating a third area of the non-display area in FIG. 12.

### DETAILED DESCRIPTION

In this specification, when a component (or, an area, a layer, a part, etc.) is referred to as being “on”, “connected to” or “coupled to” another component, this means that the component may be directly on, connected to, or coupled to the other component or a third component may be present therebetween.

Identical reference numerals refer to identical components. Additionally, in the drawings, the thicknesses, proportions, and dimensions of components are exaggerated for effective description. As used herein, the term “and/or” includes all of one or more combinations defined by related components.

Terms such as first, second, and the like may be used to describe various components, but the components should not be limited by the terms. The terms may be used only for distinguishing one component from other components. For example, without departing the scope of the present disclosure, a first component may be referred to as a second component, and similarly, the second component may also be referred to as the first component. The terms of a singular form may include plural forms unless otherwise specified.

In addition, terms such as “below”, “under”, “above”, and “over” are used to describe a relationship between components illustrated in the drawings. The terms are relative concepts and are described based on directions illustrated in the drawing.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

Unless otherwise defined, all terms used herein, including technical or scientific terms, have the same meanings as those generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

Hereinafter, aspects of some embodiments of the present disclosure will be described in more detail with reference to the accompanying drawings.

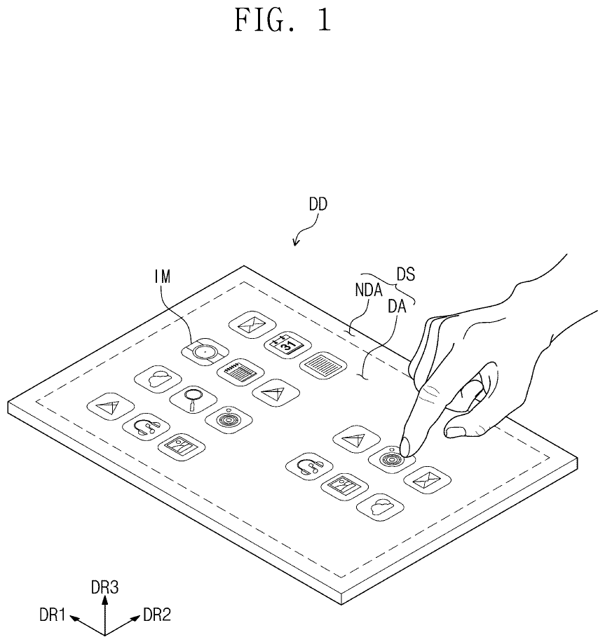

FIG. 1 is a perspective view of a display device DD according to some embodiments of the present disclosure.

Referring to FIG. 1, the display device DD according to some embodiments of the present disclosure may have a rectangular shape with long sides extending in a first direction DR1 and short sides extending in a second direction DR2 crossing the first direction DR1. However, without being limited thereto, the display device DD may have various shapes such as a circular shape, a polygonal shape, and the like. Hereinafter, a direction perpendicular (or substantially perpendicular) to a plane defined by the first direction DR1 and the second direction DR2 is defined as a third direction DR3. The phrases “when viewed from above the plane” or “in a plan view” used herein may mean that it is viewed from the third direction DR3 or from a direction perpendicular or normal with respect to a display surface of the display device DD.

The upper surface of the display device DD may be defined as a display surface DS and may have a plane defined by the first direction DR1 and the second direction DR2. Images IM generated by the display device DD may be provided to a user through the display surface DS.

The display surface DS may include a display area DA and a non-display area NDA around the display area DA. The display area DA displays images, and the non-display area NDA does not display images. The non-display area NDA may surround the display area DA. However, without being limited thereto, the non-display area NDA may not be located on one side of the display area DA.

The display device (DD) illustrated in FIG. 1 may be included in various electronic devices. The electronic devices may include, for example, at least one of a portable communication device (e.g., a smart phone), a tablet device, a portable multimedia device, a wearable device (e.g., AR glasses or VR electronic devices), various types of vehicle display devices, a smart watch, or home appliance devices.

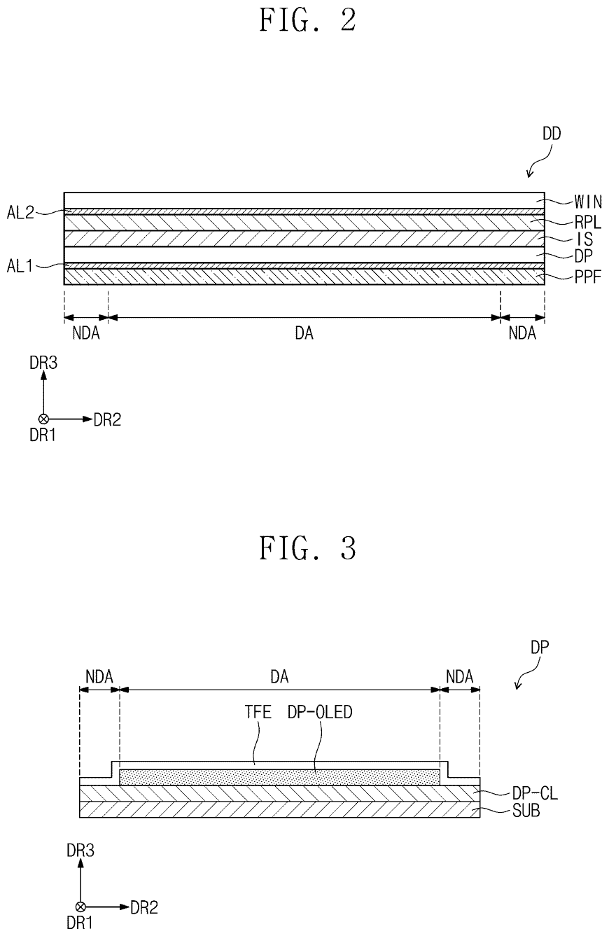

FIG. 2 is a sectional view of the display device DD illustrated in FIG. 1.

Referring to FIG. 2, the display device DD may include a display panel DP, an input sensor IS, an anti-reflective layer RPL, a window WIN, a panel protection film PPF, and first and second adhesive layers AL1 and AL2. According to some embodiments of the present disclosure, the input sensor IS may be omitted.

The display panel DP according to some embodiments of the present disclosure may be an emissive display panel, but is not particularly limited. For example, the display panel DP may be an organic light emitting display panel or an inorganic light emitting display panel. An emissive layer of the organic light emitting display panel may include an organic luminescent material. An emissive layer of the inorganic light emitting display panel may include quantum dots and quantum rods. Hereinafter, it will be illustrated that the display panel DP is an organic light emitting display panel.

The input sensor IS may be located on the display panel DP. The input sensor IS may include a plurality of sensors for sensing an external input in a capacitance type. The input sensor IS may be directly formed on the display panel DP when the display device DD is manufactured. However, without being limited thereto, the input sensor IS may be manufactured as a panel separate from the display panel DP and may be attached to the display panel DP by an adhesive layer.

The anti-reflective layer RPL may be located on the input sensor IS. The anti-reflective layer RPL may be directly formed on the input sensor IS when the display device DD is manufactured. The anti-reflective layer RPL may include color filters and may further include a black matrix.

However, without being limited thereto, the anti-reflective layer RPL may be manufactured as a separate panel and may be attached to the input sensor IS through an adhesive layer. The anti-reflective layer RPL may include an optical film such as a polarizer film. The anti-reflective layer RPL may decrease the reflectance of external light incident toward the display panel DP from above the display device DD. The external light may not be visible to the user due to the anti-reflective layer RPL.

The window WIN may be located on the anti-reflective layer RPL. The window WIN may protect the display panel DP, the input sensor IS, and the anti-reflective layer RPL from external scratches and impacts.

The panel protection film PPF may be located under the display panel DP. The panel protection film PPF may protect a lower portion of the display panel DP. The panel protection film PPF may include a flexible plastic material such as polyethylene terephthalate (PET).

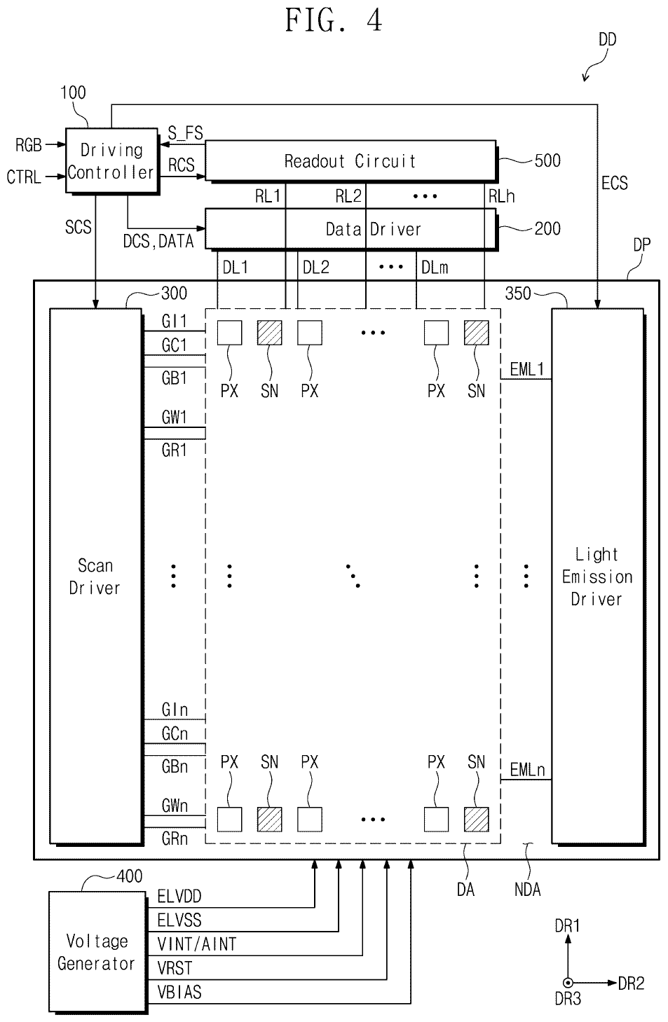

FIG. 3 is a sectional view of the display panel DP illustrated in FIG. 2.

Referring to FIG. 3, the display panel DP may include a base layer SUB, a circuit element layer DP-CL located on the base layer SUB, a display element layer DP-OLED located on the circuit element layer DP-CL, and a thin film encapsulation layer TFE located on the display element layer DP-OLED.

The base layer SUB may include a display area DA and a non-display area NDA around the display area DA, like the display device DD of FIG. 1. The base layer SUB may include a flexible plastic material, such as polyimide (PI), or glass.

The circuit element layer DP-CL may include a driving circuit of a light emitting element and a driving circuit of an optical sensor. The display element layer DP-OLED may include the light emitting element and the light sensing element. The thin film encapsulation layer TFE may be located on the circuit element layer DP-CL to cover the display element layer DP-OLED. The thin film encapsulation layer TFE may protect pixels from moisture, oxygen, and external foreign matter.

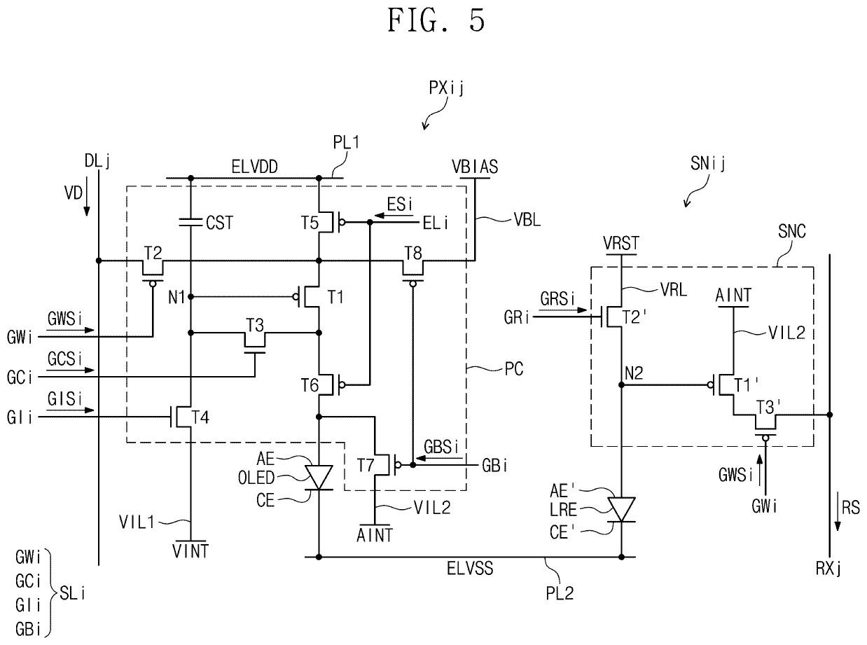

FIG. 4 is a block diagram of the display device DD according to some embodiments of the present disclosure.

Referring to FIG. 4, the display device DD includes the display panel DP, a driving controller 100, and a driving circuit of the display device DD. According to some embodiments of the present disclosure, the driving circuit of the display device DD includes a data driver 200, a scan driver 300, a light emission driver 350, a voltage generator 400, and a readout circuit 500. according to some embodiments of the present disclosure, the voltage generator 400 and the readout circuit 500, together with the driving controller 100, may be implemented as one driver IC.

The display panel DP may include a plurality of pixels PX located in the display area DA and a plurality of optical sensors SN located in the display area DA. According to some embodiments of the present disclosure, each of the optical sensors SN may be located between two pixels PX adjacent to each other. However, an arrangement relationship between the optical sensors SN and the pixels PX is not limited thereto.

The display panel DP may include initialization scan lines Gl1 to Gln, compensation scan lines GC1 to GCn, bias scan lines GB1 to GBn, write scan lines GW1 to GWn, light emission control lines EML1 to EMLn, reset scan lines GR1 to GRn, data lines DL1 to DLm, and readout lines RL1 to RLh. The initialization scan lines Gl1 to Gln, the compensation scan lines GC1 to GCn, the bias scan lines GB1 to GBn, the write scan lines GW1 to GWn, the light emission control lines EML1 to EMLn, and the reset scan lines GR1 to GRn extend in the second direction DR2. The data lines DL1 to DLm and the readout lines RL1 to RLh extend in the first direction DR1.

The pixels PX are electrically connected to the initialization scan lines GI1 to Gln, the compensation scan lines GC1 to GCn, the write scan lines GW1 to GWn, the bias scan lines GB1 to GBn, the light emission control lines EML1 to EMLn, and the data lines DL1 to DLm. However, the number of signal lines connected to each of the pixels PX may be changed without being limited thereto.

The optical sensors SN are electrically connected to the write scan lines GW1 to GWn, the reset scan lines GR1 to GRn, and the readout lines RL1 to RLh. The number of signal lines connected to each of the optical sensors SN may be changed without being limited thereto.

The driving controller 100 receives an image signal RGB and a control signal CTRL. The driving controller 100 generates an image data signal DATA by converting the data format of the image signal RGB according to the specification of an interface with the data driver 200. The driving controller 100 outputs a first control signal DCS, a second control signal SCS, a third control signal ECS, and a fourth control signal RCS.

The data driver 200 receives the first control signal DCS and the image data signal DATA from the driving controller 100. The data driver 200 converts the image data signal DATA into data signals and outputs the data signals to the plurality of data lines DL1 to DLm that will be described below. The data signals are analog voltages corresponding to gray level values of the image data signal DATA.

The scan driver 300 receives the second control signal SCS from the driving controller 100. In response to the second control signal SCS, the scan driver 300 outputs initialization scan signals and compensation scan signals to the initialization scan lines Gl1 to Gln and the compensation scan lines GC1 to GCn. Furthermore, in response to the second control signal SCS, the scan driver 300 may output write scan signals to the write scan lines GW1 to GWn and may output black scan signals to the bias scan lines GB1 to GBn. In addition, in response to the second control signal SCS, the scan driver 300 may output reset scan signals to the reset scan lines GR1 to GRn.

The light emission driver 350 receives the third control signal ECS from the driving controller 100. The light emission driver 350 may output light emission control signals to the light emission control lines EML1 to EMLn in response to the third control signal ECS. Alternatively, the scan driver 300 may be connected to the light emission control lines EML1 to EMLn. In this case, the light emission driver 350 may be omitted, and the scan driver 300 may output the light emission control signals to the light emission control lines EML1 to EMLn.

The readout circuit 500 receives the fourth control signal RCS from the driving controller 100. The readout circuit 500 may receive sensing signals from the readout lines RL1 to RLh in response to the fourth control signal RCS. The readout circuit 500 may process the sensing signals received from the readout lines RL1 to RLh and may provide the processed sensing signals S_FS to the driving controller 100. The driving controller 100 may recognize biometric information based on the sensing signals S_FS.

The voltage generator 400 generates voltages required for an operation of the display panel DP. According to some embodiments, the voltage generator 400 may generate a first driving voltage ELVDD, a second driving voltage ELVSS having a lower level than the first driving voltage ELVDD, a first initialization voltage VINT, a second initialization voltage AINT, a reset voltage VRST, and a bias voltage VBIAS.

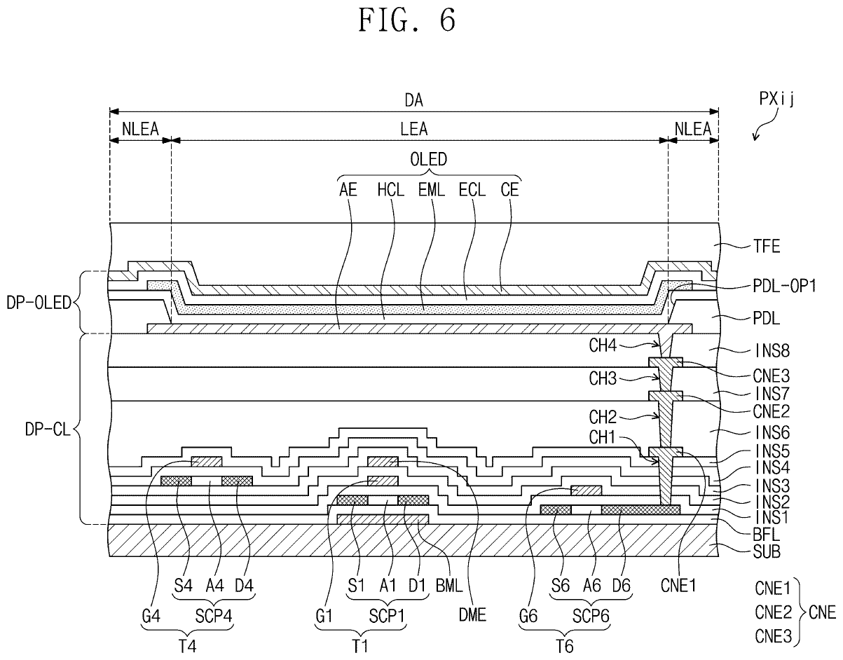

FIG. 5 is a view illustrating an equivalent circuit of one pixel PXij among the pixels PX illustrated in FIG. 4 and an optical sensor SNij adjacent to the one pixel PXij. Although FIG. 5 illustrates various components in a pixel PXij according to some embodiments, embodiments according to the present disclosure are not limited thereto, and according to various embodiments, the pixel PXij may include additional components or fewer components without departing from the spirit and scope of embodiments according to the present disclosure.

In FIG. 5, the pixel PXij connected to the i-th scan lines SLi, the i-th light emission line ELi, and the j-th data line DLj is illustrated as an example. In addition, the optical sensor SNij connected to the i-th reset scan line GRi and the j-th readout line RXj is illustrated in FIG. 5. Here, “i” and “j” are natural numbers. The i-th scan lines SLi may include the i-th initialization scan line Gli, the i-th compensation scan line GCi, the i-th bias scan line GBi, and the i-th write scan line GWi.

Referring to FIG. 5, the pixel PXij may include a pixel driving circuit PC (or, a first driving circuit) and a light emitting element OLED electrically connected to the pixel driving circuit PC. The light emitting element OLED may be turned on or off under the control of the pixel driving circuit PC.

The pixel driving circuit PC may include a plurality of transistors T1 to T8 and a capacitor CST. The transistors T1 to T8 and the capacitor CST may control the amount of current flowing through the light emitting element OLED. The light emitting element OLED may generate light having a certain luminance depending on the amount of current provided thereto.

The i-th write scan line GWi may receive the i-th write scan signal GWSi, and the i-th compensation scan line GCi may receive the i-th compensation scan signal GCSi. The i-th initialization scan line Gli may receive the i-th initialization scan signal GISi, and the i-th bias scan line GBi may receive the i-th bias scan signal GBSi. The i-th reset scan line GRi may receive the i-th reset scan signal GRSi. The i-th light emission line ELi may receive the i-th light emission signal ELSi.

A first initialization line VIL1 may receive the first initialization voltage VINT, and a second initialization line VIL2 may receive the second initialization voltage AINT. A bias line VBL may receive the bias voltage VBIAS. A first power line PL1 may receive the first driving voltage ELVDD, and a second power line PL2 may receive the second driving voltage ELVSS. The light emitting element OLED may be connected to the second power line PL2. A reset line VRL may receive the reset voltage VRST.

Each of the transistors T1 to T8 may include a source (or, a source terminal), a drain (or, a drain terminal), and a gate (or, a gate terminal). Hereinafter, in FIG. 5, for convenience, one of the source and the drain is defined as a first electrode, and the other one of the source and the drain is defined as a second electrode. In addition, the gate is defined as a gate electrode or a control electrode.

The transistors T1 to T8 may include first to eighth transistors T1 to T8. The first, second, and fifth to eighth transistors T1, T2, and T5 to T8 may be PMOS transistors. The third and fourth transistors T3 and T4 may be NMOS transistors.

The first transistor T1 may be defined as a driving transistor, and the second transistor T2 may be defined as a switching transistor. The third transistor T3 may be defined as a compensation transistor. The fourth transistor T4 and the seventh transistor T7 may be defined as initialization transistors. The fifth transistor T5 and the sixth transistor T6 may be defined as light emission control transistors. The eighth transistor T8 may be defined as a bias transistor.

The light emitting element OLED may include an organic light emitting diode. The light emitting element OLED may include a first electrode, a second electrode, and an emissive layer located between the first electrode and the second electrode. According to some embodiments, for convenience of description, the first electrode is described as an anode AE, and the second electrode is described as a cathode CE. The anode AE may be electrically connected to the first power line PL1 through the sixth, first, and fifth transistors T6, T1, and T5. The cathode CE may be electrically connected to the second power line PL2.

The first transistor T1 may be located between the fifth transistor T5 and the sixth transistor T6 and may be connected to the fifth transistor T5 and the sixth transistor T6. The first transistor T1 may be connected to the first power line PL1 through the fifth transistor T5 and may be connected to the anode AE through the sixth transistor T6.

The first transistor T1 may include a first electrode connected to the first power line PL1 through the fifth transistor T5, a second electrode connected to the anode AE through the sixth transistor T6, and a gate electrode connected to a first node N1.

The first electrode of the first transistor T1 may be connected to the fifth transistor T5, and the second electrode of the first transistor T1 may be connected to the sixth transistor T6. The first transistor T1 may control the amount of current flowing through the light emitting element OLED depending on the voltage of the first node N1 applied to the gate electrode of the first transistor T1.

The second transistor T2 may be located between the first transistor T1 and the j-th data line DLj and may be connected to the first transistor T1 and the j-th data line DLj. The second transistor T2 may include a first electrode connected to the j-th data line DLj, a second electrode connected to the first electrode of the first transistor T1, and a gate electrode connected to the i-th write scan line GWi.

The second transistor T2 may be turned on by the i-th write scan signal GWSi applied through the i-th write scan line GWi and may electrically connect the j-th data line DLj and the first electrode of the first transistor T1. The second transistor T2 may perform a switching operation of providing a data voltage VD applied through the j-th data line DLj to the first electrode of the first transistor T1.

The third transistor T3 may be connected to the second electrode of the first transistor T1 and the first node N1. The third transistor T3 may include a first electrode connected to the second electrode of the first transistor T1, a second electrode connected to the first node N1, and a gate electrode connected to the i-th compensation scan line GCi.

The third transistor T3 may be turned on by the i-th compensation scan signal GCSi applied through the i-th compensation scan line GCi and may electrically connect the second electrode of the first transistor T1 and the gate electrode of the first transistor T1. When the third transistor T3 is turned on, the first transistor T1 and the third transistor T3 may be connected in the form of a diode.

The fourth transistor T4 may be connected to the first node N1. The fourth transistor T4 may include a first electrode connected to the first node N1, a second electrode connected to the first initialization line VIL1, and a gate electrode connected to the i-th initialization scan line Gli. The fourth transistor T4 may be turned on by the i-th initialization scan signal GISi applied through the i-th initialization scan line Gli and may provide the first initialization voltage VINT applied through the first initialization line VIL1 to the first node N1.

The fifth transistor T5 may include a first electrode connected to the first power line PL1, a second electrode connected to the first electrode of the first transistor T1, and a gate electrode connected to the i-th light emission line ELi. The sixth transistor T6 may include a first electrode connected to the second electrode of the first transistor T1, a second electrode connected to the anode AE, and a gate electrode connected to the i-th light emission line ELi.

The fifth transistor T5 and the sixth transistor T6 may be turned on by the i-th light emission signal ESi applied through the i-th light emission line ELi. The first driving voltage ELVDD may be provided to the light emitting element OLED by the turned-on fifth transistor T5 and the turned-on six transistor T6, and a driving current may flow through the light emitting element OLED. Accordingly, the light emitting element OLED may emit light.

The seventh transistor T7 may include a first electrode connected to the anode AE, a second electrode connected to the second initialization line VIL2, and a gate electrode connected to the i-th bias scan line GBi. The seventh transistor T7 may be turned on by the i-th bias scan signal GBSi applied through the i-th bias scan line GBi and may provide the second initialization voltage AINT received through the second initialization line VIL2 to the anode AE of the light emitting element OLED.

According to some embodiments of the present disclosure, the seventh transistor T7 may be omitted. According to some embodiments of the present disclosure, the second initialization voltage AINT may have a level different from that of the first initialization voltage VINT. However, without being limited thereto, the second initialization voltage AINT may have the same level as the first initialization voltage VINT.

The seventh transistor T7 may relatively improve the ability of the pixel PXij to express black. When the seventh transistor T7 is turned on, a parasitic capacitor of the light emitting element OLED may be discharged. Accordingly, when black luminance is implemented, the light emitting element OLED may not emit light due to the leakage current of the first transistor T1, and thus the ability to express black may be relatively improved.

The capacitor CST may include a first electrode connected to the first power line PL1 and a second electrode connected to the first node N1. When the fifth transistor T5 and the sixth transistor T6 are turned on, the amount of current flowing through the first transistor T1 may be determined depending on the voltage stored in the capacitor CST.

The eighth transistor T8 may include a first electrode connected to the bias line VBL, a second electrode connected to the first electrode of the first transistor T1, and a gate electrode connected to the i-th bias scan line GBi. According to some embodiments of the present disclosure, the eighth transistor T8 may be omitted.

The eighth transistor T8 may be turned on by the i-th bias scan signal GBSi and may provide the bias voltage VBIAS to the first electrode of the first transistor T1. As the bias voltage VBIAS is applied to the first transistor T1, the movement of the hysteresis curve of the first transistor T1 may be suppressed.

The optical sensor SNij may include a sensor driving circuit SNC (or, a second driving circuit) and a light sensing element LRE electrically connected to the sensor driving circuit SNC. The sensor driving circuit SNC may sense an operation of the light sensing element LRE.

The sensor driving circuit SNC may include a first sensing transistor T1′, a second sensing transistor T2′, and a third sensing transistor T3′. The first and third sensing transistors T1′ and T3′ may be PMOS transistors, and the second sensing transistor T2′ may be an NMOS transistor.

The light sensing element LRE may be defined as a photo diode. The light sensing element LRE may convert light energy incident from the outside into electrical energy. The light sensing element LRE may include a first electrode, a second electrode, and a photoelectric conversion layer located between the first electrode and the second electrode. According to some embodiments, for convenience of description, the first electrode is described as an anode AE′, and the second electrode is described as a cathode CE′. The anode AE′ may be connected to a second node N2, and the cathode CE′ may be connected to the second power line PL2. Meanwhile, to distinguish the anode AE and the cathode CE of the light emitting element OLED from the anode AE′ and the cathode CE′ of the light sensing element LRE, the anode AE and the cathode CE of the light emitting element OLED may be defined as a first electrode and a second electrode, respectively, and the anode AE′ and the cathode CE′ of the light sensing element LRE may be defined as a first-first electrode and a second-first electrode, respectively.

The first sensing transistor T1′ may be connected to the light sensing element LRE, the second sensing transistor T2′, and the third sensing transistor T3′. The first sensing transistor T1′ may include a first electrode that receives the second initialization voltage AINT, a gate electrode connected to the second node N2, and a second electrode connected to the third sensing transistor T3′. The first electrode of the first sensing transistor T1′ may be connected to the second initialization line VIL2 to receive the second initialization voltage AINT. The second sensing transistor T2′ may include a first electrode connected to the second node N2, a gate electrode connected to the i-th reset scan line GRi, and a second electrode connected to the reset line VRL. The third sensing transistor T3′ may include a first electrode connected to the second electrode of the first sensing transistor T1′, a gate electrode connected to the i-th write scan line GWi, and a second electrode connected to the readout line RXj. The third sensing transistor T3′ may be turned on by the i-th write scan signal GWSi received through the i-th write scan line GWi.

The second sensing transistor T2′ may be turned on by the i-th reset scan signal GRSi received through the i-th reset scan line GRi. The turned-on second sensing transistor T2′ may receive the reset voltage VRST and may provide the reset voltage VRST to the second node N2. The second node N2 may be reset by the reset voltage VRST. According to some embodiments of the present disclosure, all the optical sensors SN illustrated in FIG. 4 may receive the same reset scan signal. The second sensing transistors T2′ of all the optical sensors SN may be turned on at the same timing and may be turned off at the same timing.

The i-th write scan signal GWSi may be applied to the gate electrode of the third sensing transistor T3′, and the third sensing transistor T3′ may be turned on accordingly. The first sensing transistor T1′ may be connected to the readout line RXj by the turned-on third sensing transistor T3′.

The light sensing element LRE may receive light and may convert the light into an electrical signal. At this time, the voltage of the second node N2 may be changed. When the first sensing transistor T1′ is turned on, the second initialization voltage AINT provided to the first sensing transistor T1′ may be controlled depending on a change in the voltage of the second node N2 and may be provided to the readout line RXj through the third sensing transistor T3′. Accordingly, a signal sensed by the light sensing element LRE may be output through the readout line RXj as a sensing signal RS.

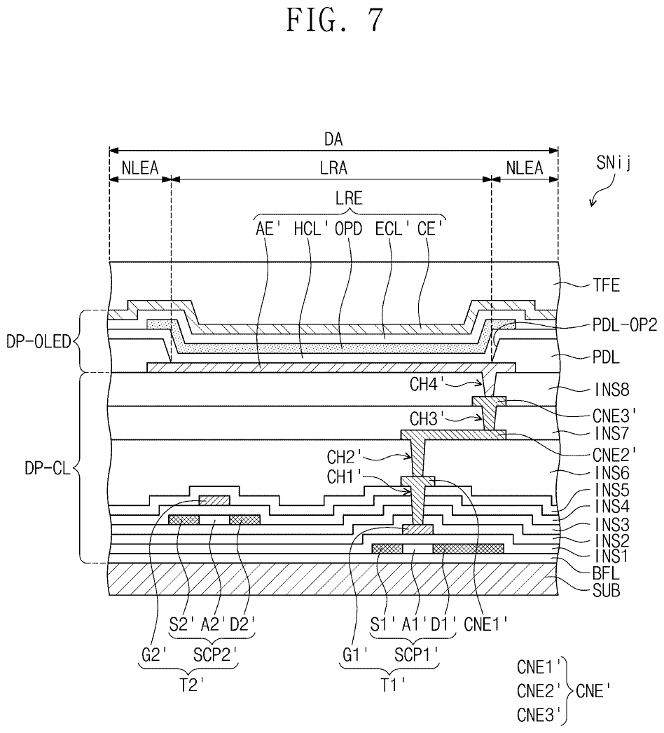

FIG. 6 is a sectional view illustrating the light emitting element OLED, the first transistor T1, the fourth transistor T4, and the sixth transistor T6 of the pixel PXij illustrated in FIG. 5.

In FIG. 6, the first, fourth, and sixth transistors T1, T4, and T6 of the pixel driving circuit PC of FIG. 5 are illustrated. Referring to FIG. 6, a shielding layer BML may be located on the base layer SUB. The shielding layer BML may overlap the first transistor T1. The shielding layer BML may include metal and may receive a constant voltage. When the constant voltage is applied to the shielding layer BML, the threshold voltage Vth of the first transistor T1 arranged over the shielding layer BML may remain unchanged. In addition, the shielding layer BML may block light incident to the first transistor T1 from below the shielding layer BML. For example, the shielding layer BML may include reflective metal. According to some embodiments of the present disclosure, the shielding layer BML may be omitted.

A buffer layer BFL may be located on the base layer SUB. The buffer layer BFL may include an inorganic layer. The buffer layer BFL may cover the shielding layer BML. A semiconductor layer SCP1 (or, a semiconductor pattern area, hereinafter, referred to as the first semiconductor layer) of the first transistor T1 and a semiconductor layer SCP6 (or, a semiconductor pattern area, hereinafter, referred to as the sixth semiconductor layer) of the sixth transistor T6 may be located on the buffer layer BFL. The first and sixth semiconductor layers SCP1 and SCP6 may include poly-silicon. However, without being limited thereto, the first and sixth semiconductor layers SCP1 and SCP6 may include amorphous silicon.

The first and sixth semiconductor layers SCP1 and SCP6 may be formed through the same process, and partial areas of the first and sixth semiconductor layers SCP1 and SCP6 may be doped with an N-type dopant or a P-type dopant. Each of the first and sixth semiconductor layers SCP1 and SCP6 may include highly-doped areas and a lightly-doped area. The highly-doped areas have a higher conductivity than the lightly-doped area. The highly-doped areas may correspond (or substantially correspond) to the source and the drain of each of the first and sixth transistors T1 and T6. The lightly-doped area may correspond (or substantially correspond) to the active (or, channel) area of each of the first and sixth transistors T1 and T6.

The highly-doped areas of the first semiconductor layer SCP1 may include a first source area S1 and a first drain area D1. The lightly-doped area of the first semiconductor layer SCP1 is defined as a first channel area A1 and located between the first source area S1 and the first drain area D1. Similarly to the first semiconductor layer SCP1, the sixth semiconductor layer SCP6 may include a sixth source area S6, a sixth channel area A6, and a sixth drain area D6.

Although the first semiconductor layer SCP1 and the sixth semiconductor layer SCP6 are spaced apart from each other on the section of FIG. 6, the first semiconductor layer SCP1 and the sixth semiconductor layer SCP6 may have a one-body shape when viewed from above the plane (or in a plan view). In other words, the first semiconductor layer SCP1 and the sixth semiconductor layer SCP6 may be different portions or areas of one semiconductor pattern.

A first insulating layer INS1 may be located on the buffer layer BFL to cover the first and sixth semiconductor layers SCP1 and SCP6. The gate electrodes of the first and sixth transistors T1 and T6 are located on the first insulating layer INS1. The gate electrodes of the first and sixth transistors T1 and T6 may be formed through the same process. Hereinafter, the gate electrode of the first transistor T1 is defined as a first gate electrode G1, and the gate electrode of the sixth transistor T6 is defined as a sixth gate electrode G6. A metal layer formed on the first insulating layer INS1, such as the first gate electrode G1, may be defined as a first gate layer. The first gate layer may further include a plurality of patterns as well as the first gate electrode G1 and the sixth gate electrode G6.

A second insulating layer INS2 may be located on the first insulating layer INS1 to cover the first and sixth gate electrodes G1 and G6. A dummy electrode DME may be located on the second insulating layer INS2. The dummy electrode DME may be arranged over the first gate electrode G1 and may overlap the first gate electrode G1 when viewed from above the plane (or in a plan view). The dummy electrode DME may form the above-described capacitor CST together with the first gate electrode G1. In other words, the first gate electrode G1 corresponds to one electrode of the capacitor CST, and the dummy electrode DME corresponds to the other electrode of the capacitor CST. A metal layer formed on the second insulating layer INS2, such as the dummy electrode DME, may be defined as a second gate layer. The second gate layer may further include a plurality of patterns as well as the dummy electrode DME.

A third insulating layer INS3 may be located on the second insulating layer INS2 to cover the dummy electrode DME. A semiconductor layer SCP4 (or, a semiconductor pattern area, hereinafter, referred to as the fourth semiconductor layer) of the fourth transistor T4 may be located on the third insulating layer INS3. The fourth semiconductor layer SCP4 may include an oxide semiconductor including metal oxide. The oxide semiconductor may include a crystalline or amorphous oxide semiconductor.

The fourth semiconductor layer SCP4 may include a plurality of areas distinguished from one another depending on whether the metal oxide is reduced or not. Areas where the metal oxide is reduced (hereinafter, referred to as the reduced areas) have a higher conductivity than an area where the metal oxide is not reduced (hereinafter, referred to as the non-reduced area). The reduced areas may correspond (or substantially correspond) to the source and the drain of the fourth transistor T4. The non-reduced area may correspond (or substantially correspond) to the active (or, channel) area of the fourth transistor T4.

The reduced areas of the fourth semiconductor layer SCP4 may include a fourth source area S4 and a fourth drain area D4. A fourth channel area A4 may be located between the fourth source area S4 and the fourth drain area D4.

A fourth insulating layer INS4 may be located on the third insulating layer INS3 to cover the fourth semiconductor layer SCP4. A fourth gate electrode G4 of the fourth transistor T4 may be located on the fourth insulating layer INS4. A metal layer formed on the fourth insulating layer INS4, such as the fourth gate electrode G4, may be defined as a third gate layer. The third gate layer may further include a plurality of patterns as well as the fourth gate electrode G4.

A fifth insulating layer INS5 may be located on the fourth insulating layer INS4 to cover the fourth gate electrode G4. The buffer layer BFL and the first to fifth insulating layers INS1 to INS5 may include inorganic layers.

A connecting electrode CNE may be located between the sixth transistor T6 and the light emitting element OLED. The connecting electrode CNE may electrically connect the sixth transistor T6 and the light emitting element OLED. The connecting electrode CNE may include a first connecting electrode CNE1, a second connecting electrode CNE2 arranged over the first connecting electrode CNE1, and a third connecting electrode CNE3 arranged over the second connecting electrode CNE2.

The first connecting electrode CNE1 may be located on the fifth insulating layer INS5 and may be connected to the sixth drain area D6 through a first contact hole CH1 defined in the first to fifth insulating layers INS1 to INS5. A metal layer formed on the fifth insulating layer INS5, such as the first connecting electrode CNE1, may be defined as a first source/drain layer. The first source/drain layer may further include a plurality of patterns as well as the first connecting electrode CNE1.

A sixth insulating layer INS6 may be located on the fifth insulating layer INS5 to cover the first connecting electrode CNE1. The second connecting electrode CNE2 may be located on the sixth insulating layer INS6. The second connecting electrode CNE2 may be connected to the first connecting electrode CNE1 through a second contact hole CH2 defined in the sixth insulating layer INS6. A metal layer formed on the sixth insulating layer INS6, such as the second connecting electrode CNE2, may be defined as a second source/drain layer. The second source/drain layer may further include a plurality of patterns as well as the second connecting electrode CNE2.

A seventh insulating layer INS7 may be located on the sixth insulating layer INS6 to cover the second connecting electrode CNE2. The third connecting electrode CNE3 may be located on the seventh insulating layer INS7. The third connecting electrode CNE3 may be connected to the second connecting electrode CNE2 through a third contact hole CH3 defined in the seventh insulating layer INS7. A metal layer formed on the seventh insulating layer INS7, such as the third connecting electrode CNE3, may be defined as a third source/drain layer. The third source/drain layer may further include a plurality of patterns as well as the third connecting electrode CNE3.

An eighth insulating layer INS8 may be located on the seventh insulating layer INS7 to cover the third connecting electrode CNE3. The light emitting element OLED is located on the eighth insulating layer INS8. The sixth to eighth insulating layers INS6 to INS8 may include an inorganic layer or an organic layer. According to some embodiments, each of the sixth to eighth insulating layers INS6 to INS8 may include an organic layer.

The light emitting element OLED may include the first electrode AE, the second electrode CE, a hole control layer HCL, an electron control layer ECL, and the emissive layer EML. The first electrode AE may be the anode AE illustrated in FIG. 5, and the second electrode CE may be the cathode CE illustrated in FIG. 5. The second electrode CE may be arranged over the first electrode AE. The hole control layer HCL and the electron control layer ECL may be located between the first electrode AE and the second electrode CE. The emissive layer EML may be located between the hole control layer HCL and the electron control layer ECL. The first electrode AE may be located on the eighth insulating layer INS8. The first electrode AE may be electrically connected to the third connecting electrode CNE3 through a fourth contact hole CH4 defined in the eighth insulating layer INS8.

A pixel defining layer PDL exposing a portion of the first electrode AE may be located on the first electrode AE and the eighth insulating layer INS8. A first opening PDL-OP1 for exposing the portion of the first electrode AE may be defined in the pixel defining layer PDL. The first opening PDL-OP1 corresponds to an emissive area LEA. The display area DA may include the emissive area LEA corresponding to the first opening PDL-OP1 and a non-emissive area NLEA adjacent to the emissive area LEA.

The hole control layer HCL may be located on the first electrode AE and the pixel defining layer PDL. The hole control layer HCL may be commonly arranged in the emissive area LEA and the non-emissive area NLEA. The hole control layer HCL may include a hole transport layer and a hole injection layer.

The emissive layer EML may be located on the hole control layer HCL. The emissive layer EML may be located in an area corresponding to the first opening PDL-OP1. The emissive layer EML may include an organic material and/or an inorganic material. The emissive layer EML may generate one of red light, green light, and blue light.

The electron control layer ECL may be located on the emissive layer EML and the hole control layer HCL. The electron control layer ECL may be commonly located in the emissive area LEA and the non-emissive area NLEA. The electron control layer ECL may include an electron transport layer and an electron injection layer.

The second electrode CE may be located on the electron control layer ECL. The second electrode CE may be commonly arranged in the pixels PX illustrated in FIG. 4. That is, the second electrode CE may be commonly arranged over the emissive layers EML of the pixels PX.

The layers from the buffer layer BFL to the eighth insulating layer INS8 may be defined as the circuit element layer DP-CL. The layer in which the light emitting element OLED is located may be defined as the display element layer DP-OLED.

The thin film encapsulation layer TFE may be located on the light emitting element OLED. The thin film encapsulation layer TFE may include an inorganic layer, an organic layer, and an in organic layer sequentially stacked one above another. The inorganic layers may include an inorganic material and may protect the pixels from moisture/oxygen. The organic layer may include an organic material and may protect the element emitting element OLED from foreign matter such as dust particles.

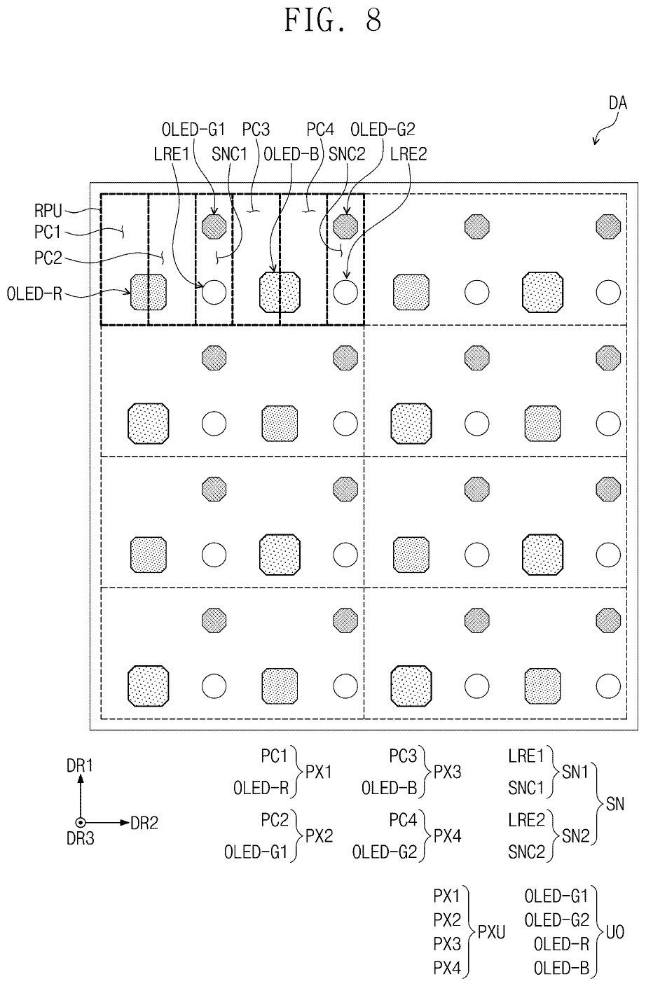

FIG. 7 is a sectional view illustrating the light sensing element LRE, the first sensing transistor T1′, and the second sensing transistor T2′ of the optical sensor SNij illustrated in FIG. 5. Detailed description of components identical to the components described above with reference to FIG. 6 refers to the description of FIG. 6.

A semiconductor layer SCP1′ (hereinafter, referred to as the first sensing semiconductor layer) of the first sensing transistor T1′ may be formed through the same process as the first semiconductor layer SCP1 of FIG. 6, and a semiconductor layer SCP2′ (hereinafter, referred to as the second sensing semiconductor layer) of the second sensing transistor T2′ may be formed through the same process as the fourth semiconductor layer SCP4 of FIG. 6. The first sensing semiconductor layer SCP1′ may include a first source area S1′, a first drain area D1′, and a first channel area A1′. The second sensing semiconductor layer SCP2′ may include a second source area S2′, a second drain area D2′, and a second channel area A2′.

The stacked structure of the first sensing transistor T1′ may be the same (or substantially the same) as the stacked structure of the first transistor T1 illustrated in FIG. 6. The stacked structure of the second sensing transistor T2′ may be the same (or substantially the same) as the stacked structure of the fourth transistor T4 illustrated in FIG. 6. According to some embodiments, the stacked structure of the third sensing transistor T3′ may be the same (or substantially the same) as the stacked structure of the first sensing transistor T1′.

A connecting electrode CNE′ may include a first connecting electrode CNE1′ (or, a first sensing connecting electrode), a second connecting electrode CNE2′ (or, a second sensing connecting electrode), and a third connecting electrode CNE3′ (or, a third sensing connecting electrode). The first connecting electrode CNE1′ may be located on the same layer as the first connecting electrode CNE1 illustrated in FIG. 6 and may be connected to a first gate electrode G1′ of the first sensing transistor T1′ through a first contact hole CH1′. Hereinafter, the first gate electrode G1′ is defined as a first sensing gate electrode G1′ so as to be distinguished from the above-described first gate electrode G1.

The second connecting electrode CNE2′ may be located on the same layer as the second connecting electrode CNE2 illustrated in FIG. 6 and may be connected to the first connecting electrode CNE1′ through a second contact hole CH2′ defined in the sixth insulating layer INS6. The third connecting electrode CNE3′ may be located on the same layer as the third connecting electrode CNE3 illustrated in FIG. 6 and may be connected to the second connecting electrode CNE2′ through a third contact hole CH3′. The first electrode AE′ may be connected to the third connecting electrode CNE3′ through a fourth contact hole CH4′ defined in the eighth insulating layer INS8.

Referring to FIG. 7, the display area DA may include a light receiving area LRA corresponding to the optical sensor SNij and a non-emissive area NLEA adjacent to the light receiving area LRA. The non-emissive area NLEA may be the non-emissive area NLEA illustrated in FIG. 6.

The light sensing element LRE may include the first electrode AE′, the second electrode CE′, a hole control layer HCL′, an electron control layer ECL′, and the photoelectric conversion layer OPD. The first electrode AE′ may be the anode AE′ illustrated in FIG. 5, and the second electrode CE′ may be the cathode CE′ illustrated in FIG. 5. A second opening PDL-OP2 for exposing a portion of the first electrode AE′ may be defined in the pixel defining layer PDL. The light receiving area LRA corresponds to the second opening PDL-OP2.

The first electrode AE′ is formed through the same process as the first electrode AE illustrated in FIG. 6. The second electrode CE′ may have a one-body shape with the second electrode CE illustrated in FIG. 6, the hole control layer HCL′ may have a one-body shape with the hole control layer HCL illustrated in FIG. 6, and the electron control layer ECL′ may have a one-body shape with the electron control layer ECL illustrated in FIG. 6. The second electrode CE′ of FIG. 7 and the second electrode CE of FIG. 6 may be different areas of a common electrode. The common electrode may be deposited through an open mask so as to have a one-body shape. The hole control layer HCL′ of FIG. 7 and the hole control layer HCL of FIG. 6 may be different areas of a common hole control layer, and the electron control layer ECL′ of FIG. 7 and the electron control layer ECL of FIG. 6 may be different areas of a common electron control layer.

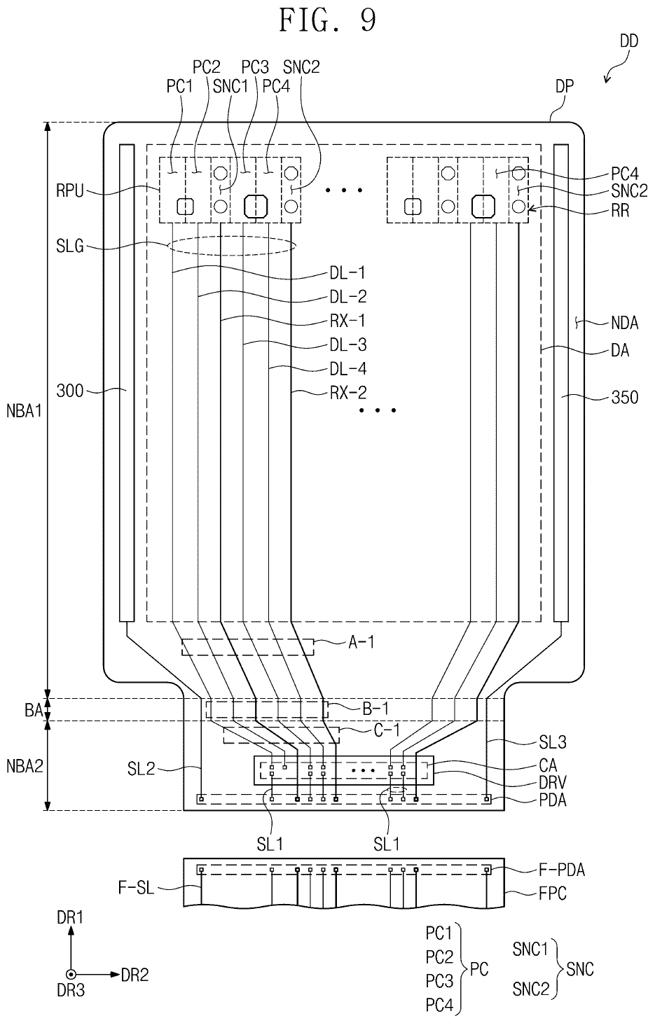

FIG. 8 is a view illustrating a planar arrangement of light emitting elements OLED and light sensing elements LRE located in a partial area of the display area DA illustrated in FIG. 4.

In FIG. 8, unit areas RPU repeatedly arranged in the display area DA are illustrated so as to be distinguished from one another. One or more pixels PX1, PX2, PX3, and PX4 and an optical sensor SN are arranged to correspond to each of the unit areas RPU. A combination of the pixels PX1, PX2, PX3, and PX4 that corresponds to the unit area RPU may be defined as a unit pixel PXU.

According to some embodiments, the unit pixel PXU includes the first to fourth pixels PX1, PX2, PX3, and PX4. However, the number of pixels in the unit pixel PXU may be changed. The first pixel PX1 may include a first light emitting element OLED-R and a first driving circuit PC1 electrically connected thereto. The second pixel PX2 may include a second-first light emitting element OLED-G1 and a first driving circuit PC2 electrically connected thereto. The third pixel PX3 may include a third light emitting element OLED-B and a first driving circuit PC3 electrically connected thereto. The fourth pixel PX4 may include a second-second light emitting element OLED-G2 and a first driving circuit PC4 electrically connected thereto.

The optical sensor SN may include first and second optical sensors SN1 and SN2. However, the number of optical sensors SN corresponding to the unit pixel PXU may be changed. The first optical sensor SN1 may include a first light sensing element LRE1 and a second driving circuit SNC1 electrically connected thereto, and the second optical sensor SN2 may include a second light sensing element LRE2 and a second driving circuit SNC2 electrically connected thereto.

The first, second-first, third, and second-second light emitting elements OLED-R, OLED-G1, OLED-B, and OLED-G2 of the unit pixel PXU and the first and second light sensing elements LRE1 and LRE2 may be arranged to overlap each of the unit areas RPU. Hereinafter, the light emitting elements OLED-R, OLED-G1, OLED-B, and OLED-G2 corresponding to the unit pixel PXU are defined as a unit light emitting element UO. The arrangement of the unit light emitting element UO and the first and second light sensing elements LRE1 and LRE2 in the unit areas RPU may be the same.

The first light emitting element OLED-R generates light of a first color, for example, red light. The second-first light emitting element OLED-G1 and the second-second light emitting element OLED-G2 generate light of a second color, for example, green light. The third light emitting element OLED-B generates light of a third color, for example, blue light. The third light emitting element OLED-B may have the largest light emitting area, and the second-first light emitting element OLED-G1 and the second-second light emitting element OLED-G2 may have the smallest light emitting area.

According to some embodiments, the first light emitting element OLED-R and the third light emitting element OLED-B may be located on the same line and may be spaced apart from each other in the second direction DR2. The first light sensing element LRE1 may be located between the first light emitting element OLED-R and the third light emitting element OLED-B in the second direction DR2. The third light emitting element OLED-B may be located between the first light sensing element LRE1 and the second light sensing element LRE2 in the second direction DR2. The second-first light emitting element OLED-G1 and the second-second light emitting element OLED-G2 may be located on the same line, but may be located on a line different from the line on which the first light emitting element OLED-R and the third light emitting element OLED-B are located. The second-first light emitting element OLED-G1 may be located on one side of the first light sensing element LRE1 in the first direction DR1, and the second-second light emitting element OLED-G2 may be located on one side of the second light sensing element LRE2 in the first direction DR1. According to some embodiments, the second-first light emitting element OLED-G1 is located on the upper side of the first light sensing element LRE1.

According to some embodiments of the present disclosure, one of the first light sensing element LRE1 and the second light sensing element LRE2 may be omitted. According to some embodiments of the present disclosure, a light sensing element may be additionally located on the upper side of the first light emitting element OLED-R in the first direction DR1, or a light sensing element may be additionally located on the upper side of the third light emitting element OLED-B in the first direction DR1. That is, four optical sensors may be arranged to correspond to the unit area RPU.

According to some embodiments of the present disclosure, the unit areas RPU may be distinguished from one another based on the arrangement of the first driving circuits PC1, PC2, PC3, and PC4 and the second driving circuits SNC1 and SNC2. Four first driving circuits PC1, PC2, PC3, and PC4 and two second driving circuits SNC1 and SNC2 may be located in each of the unit areas RPU. The four first driving circuits PC1, PC2, PC3, and PC4 may be defined as the first-first driving circuit PC1, the first-second driving circuit PC2, the first-third driving circuit PC3, and the first-fourth driving circuit PC4, and the two second driving circuits SNC1 and SNC2 may be defined as the second-first driving circuit SNC1 and the second-second driving circuit SNC2.

Each of the first light emitting element OLED-R, the second-first light emitting element OLED-G1, the third light emitting element OLED-B, and the second-second light emitting element OLED-G2 may or may not overlap a corresponding driving circuit among the first-first driving circuit PC1, the first-second driving circuit PC2, the first-third driving circuit PC3, and the first-fourth driving circuit PC4 when viewed from above the plane (or in a plan view). For example, when the third connection electrode CNE3 of FIG. 6 has a shape extending on the plane, the light emitting element OLED connected thereto may not overlap the corresponding first-second driving circuit PC2, like the second-first light emitting element OLED-G1.

Although it has been described that the first-first driving circuit PC1, the first-second driving circuit PC2, the first-third driving circuit PC3, the first-fourth driving circuit PC4, the first light emitting element OLED-R, the second-first light emitting element OLED-G1, the third light emitting element OLED-B, and the second-second light emitting element OLED-G2 are all located in the unit areas RPU, the present disclosure is not limited thereto. According to some embodiments of the present disclosure, one of four first driving circuits PC1, PC2, PC3, and PC4 located in a first unit area among the unit areas RPU may be connected with one of a first light emitting element OLED-R, a second-first light emitting element OLED-G1, a third light emitting element OLED-B, and a second-second light emitting element OLED-G2 located in a second unit area adjacent to the first unit area. For example, when the third connecting electrode CNE3 of FIG. 6 further extends from the first unit area to the second unit area on the plane, a driving circuit located in the first unit area and a light emitting element located in the second unit area may form one pixel.

Furthermore, although it has been described that the second-first and second-second driving circuits SNC1 and SNC2 and the first and second light sensing elements LRE1 and LRE2 are all located in the unit areas RPU, the present disclosure is not limited thereto. For example, when the third connecting electrode CNE3′ of FIG. 3 further extends from the first unit area to the second unit area on the plane, a driving circuit located in the first unit area and a light sensing element located in the second unit area may form one optical sensor.

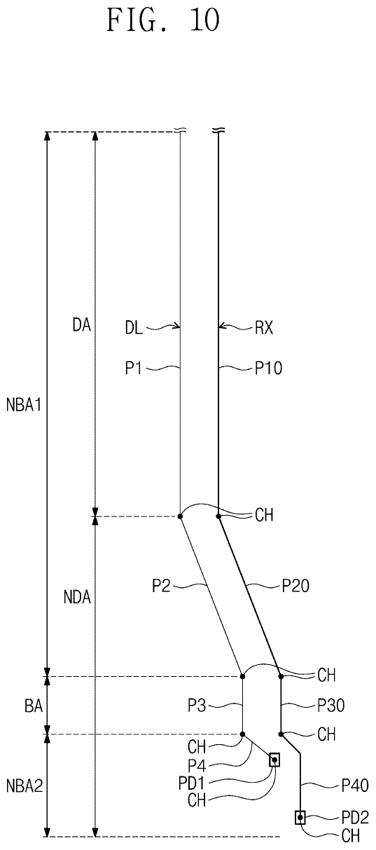

FIG. 9 is a plan view illustrating the display device DD according to some embodiments of the present disclosure.

Referring to FIG. 9, the display panel DP may include the display area DA and the non-display area NDA around the display area DA. The plurality of unit areas RPU are located in the display area DA. The unit areas RPU may be arranged in the first direction DR1 and the second direction DR2. The unit areas RPU may be arranged in a matrix form. Among the unit areas RPU, unit areas RPU located in the same row in the second direction DR2 define a unit row RR. Unit rows RR may be arranged in the first direction DR1.

According to some embodiments, the unit areas RPU are uniformly arranged throughout the display area DA. Among the unit areas RPU located in the unit row RR, the first unit area is located at one end of the display area in the second direction DR2, and the last unit area is located at an opposite end of the display area DA in the second direction DR2. The arrangement of signal line groups SLG that will be described below may prevent or reduce instances of short circuits between signal lines and may enable the optical sensors SN to be arranged throughout the display area DA.

Detailed description of each of the unit areas RPU refers to the description of the unit area RPU in FIG. 8. The first-first driving circuit PC1, the first-second driving circuit PC2, the second-first driving circuit SNC1, the first-third driving circuit PC3, the first-fourth driving circuit PC4, and the second-second driving circuit SNC2 located in each of the unit areas RPU are illustrated in FIG. 9 so as to be distinguished from one another.

The non-display area NDA includes at least a chip area CA and a pad area PDA. The pad area PDA is an area to which a printed circuit board FPC is bonded. The pad area PDA is spaced further apart from the display area DA relative to the chip area CA in the first direction DR1. The chip area CA is an area on which a driver IC DRV is mounted. The scan driver 300 and the light emission driver 350 may be located in the non-display area NDA. The scan driver 300 and the light emission driver 350 may be arranged to face each other in the second direction DR2 with the display area DA therebetween.

The display panel DP may be divided into a first area NBA1, a second area NBA2, and a bending area BA in the first direction DR1. The second area NBA2 and the bending area BA may be partial areas of the non-display area NDA. The bending area BA is located between the first area NBA1 and the second area NBA2. As the bending area BA of the display panel DP is bent, the base layer SUB (refer to FIG. 6) of the first area NBA1 and the base layer SUB (refer to FIG. 6) of the second area NBA2 may be adjacent to each other and may face each other.

The plurality of signal line groups SLG are arranged to correspond to the unit areas RPU in the unit row RR, respectively. Each of the signal line groups SLG is arranged in a corresponding unit column. The signal line groups SLG are repeating units of two or more types of signal lines. Each of the plurality of signal line groups SLG is electrically connected to a corresponding unit area RPU. The signal line group SLG is electrically connected to the unit areas RPU arranged in one unit column. The expression “the signal line group SLG is electrically connected to the unit area RPU” used herein means that signal lines in the signal line group SLG are connected to the first driving circuit PC and/or the second driving circuit SNC in the unit area RPU. The signal line groups SLG are arranged in the second direction DR2.

Each of the signal line groups SLG may include a plurality of signal lines. The number of signal lines in the signal line group SLG may be determined by the number of first driving circuits PC and the number of second driving circuits SNC that correspond to one unit area RPU. According to some embodiments, the signal line group SLG may include four data lines DL-1, DL-2, DL-3, and DL-4 and two readout lines RX-1 and RX-2. That is, the signal line group SLG may include six signal lines.

The data lines DL-1, DL-2, DL-3, and DL-4 extend from the chip area CA to the display area DA in the second direction DR2 and electrically connect the unit pixel PXU (refer to FIG. 8) to the driver IC DRV. Specifically, the data lines DL-1, DL-2, DL-3, and DL-4 electrically connect the first driving circuits PC to the driver IC DRV. End portions of the data lines DL-1, DL-2, DL-3, and DL-4 are located in the chip area CA and connected with bumps of the driver IC DRV in a one-to-one correspondence. Pad electrodes connected to the end portions of the data lines DL-1, DL-2, DL-3, and DL-4 may be bonded to the bumps of the driver IC DRV.

The readout lines RX-1 and RX-2 extend from the pad area PDA to the display area DA in the second direction DR2 and electrically connect the optical sensor SN (refer to FIG. 8) to the printed circuit board FPC. Specifically, the readout lines RX-1 and RX-2 electrically connect the second driving circuits SNC to the printed circuit board FPC. The printed circuit board FPC may include a pad area F-PDA bonded to the pad area PDA and a plurality of signal lines F-SL that transmit signals.

According to some embodiments, even though the first and second readout lines RX-1 and RX-2 extend from areas different from the areas from which the first to fourth data lines DL-1, DL-2, DL-3, and DL-4 extend, the first and second readout lines RX-1 and RX-2 may overlap the chip area CA, and therefore the first and second readout lines RX-1 and RX-2 may extend to the display area DA without short circuits between the first and second readout lines RX-1 and RX-2 and the first to fourth data lines DL-1, DL-2, DL-3, and DL-4 and may be connected to the second driving circuit SNC. Furthermore, because the signal line groups SLG are uniformly arranged in the second direction DR2, the first and second readout lines RX-1 and RX-2 may be uniformly arranged throughout the display area DA.

In addition, because the first and second readout lines RX-1 and RX-2 overlap the chip area CA, the first and second readout lines RX-1 and RX-2 may be arranged in the non-display area NDA so as not to overlap the first to fourth data lines DL-1, DL-2, DL-3, and DL-4. The middle portions of the first and second readout lines RX-1 and RX-2 overlap the pad area PDA and do not overlap the end portions of the data lines DL-1, DL-2, DL-3, and DL-4 that are connected with the bumps of the driver IC DRV, respectively. The middle portions of the first and second readout lines RX-1 and RX-2 pass between the end portions of the data lines DL-1, DL-2, DL-3, and DL-4.

Referring to FIG. 9, in a partial area of the non-display area NDA located between the chip area CA and the display area DA in the first direction DR1, the four data lines DL-1, DL-2, DL-3, and DL-4 and the two readout lines RX-1 and RX-2 are arranged in the second direction DR2 in the order of the first data line DL-1, the second data line DL-2, the first readout line RX-1, the third data line DL-3, the fourth data line DL-4, and the second readout line RX-2 so as not to overlap one another. Even though the four data lines DL-1, DL-2, DL-3, and DL-4 and the two readout lines RX-1 and RX-2 are located on the same layer, short circuits between the four data lines DL-1, DL-2, DL-3, and DL-4 and the two readout lines RX-1 and RX-2 may be prevented or reduced.

Although the signal line group SLG including the signal lines arranged in the second direction DR2 in the order of the first data line DL-1, the second data line DL-2, the first readout line RX-1, the third data line DL-3, the fourth data line DL-4, and the second readout line RX-2 has been described in these embodiments, the present disclosure is not limited thereto. The arrangement and number of signal lines in the signal line group SLG may be changed depending on the arrangement and numbers of first driving circuits PC and second driving circuits SNC located in the unit area RPU. For example, the signal line group SLG may include signal lines arranged in the order of a first data line, a second data line, a third data line, a fourth data line, and a readout line. Alternatively, the signal line group SLG may include signal lines arranged in the order of a first data line, a second data line, a readout line, a third data line, and a fourth data line. In another case, the signal line group SLG may include signal lines arranged in the order of a first data line, a first readout line, a second data line, a second readout line, a third data line, a third readout line, a fourth data line, and a fourth readout line. In yet another case, the signal line group SLG may include signal lines arranged in the order of a first data line, a second data line, and a readout line.

Signal lines other than the signal line groups SLG may be additionally located in the non-display area NDA of the display panel DP. First signal lines SL1 extend from the pad area PDA to the chip area CA and electrically connect the printed circuit board FPC to the driver IC DRV. The first signal lines SL1 may transmit the first control signal DCS and the image data signal DATA described with reference to FIG. 4. A second signal line SL2 extends from the pad area PDA to the scan driver 300 and electrically connects the printed circuit board FPC to the scan driver 300. The second signal line SL2 may transmit the second control signal SCS described with reference to FIG. 4. A third signal line SL3 extends from the pad area PDA to the light emission driver 350 and electrically connects the printed circuit board FPC to the light emission driver 350. The third signal line SL3 may transmit the third control signal ECS described with reference to FIG. 4.

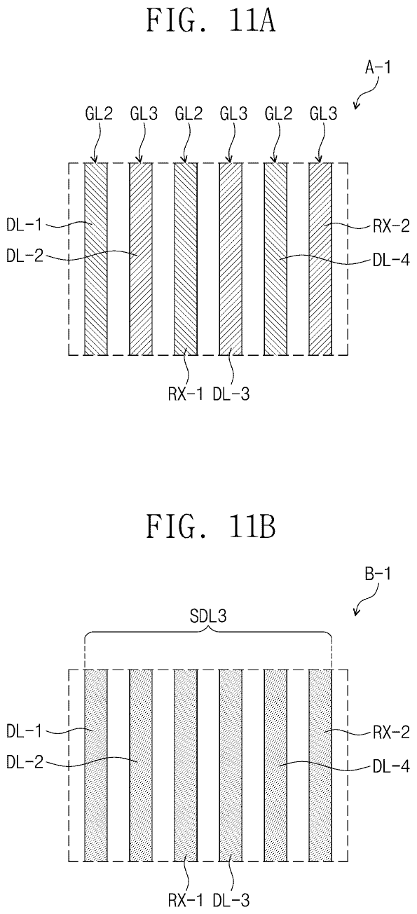

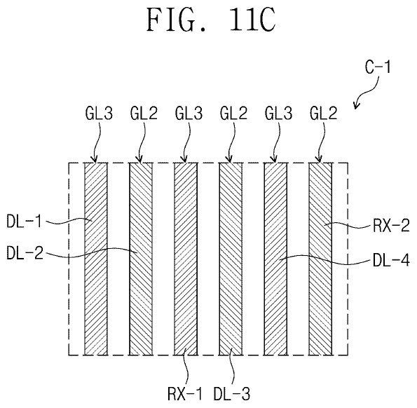

FIG. 10 is an enlarged plan view illustrating a data line DL and a readout line RX according to some embodiments of the present disclosure. FIG. 11A is an enlarged plan view illustrating a first area A-1 of the non-display area NDA in FIG. 9. FIG. 11B is an enlarged plan view illustrating a second area B-1 of the non-display area NDA in FIG. 9. FIG. 11C is an enlarged plan view illustrating a third area C-1 of the non-display area NDA in FIG. 9.

In FIG. 10, one data line DL is illustrated as a representative of the first to fourth data lines DL-1, DL-2, DL-3, and DL-4 of FIG. 9, and one readout line RX is illustrated as a representative of the first and second readout lines RX-1 and RX-2 of FIG. 9. In these embodiments, the data line DL and the readout line RX directly adjacent to each other are illustrated as an example. The expression “the data line DL and the readout line RX are directly adjacent to each other” used herein means that a signal line extending along the data line DL is not located between the data line DL and the readout line RX.

Each of the data line DL and the readout line RX may include a plurality of portions located on different layers depending on areas. The data line DL may include first to fourth portions P1 to P4, and the readout line RX may include first to fourth portions P10 to P40 corresponding to the first to fourth portions P1 to P4.

The first portion P1 of the data line DL and the first portion P10 of the readout line RX that overlap the display area DA in the first area NBA1 may be formed from one of the first source/drain layer, the second source/drain layer, and the third source/drain layer described with reference to FIGS. 6 and 7. The first portion P1 of the data line DL and the first portion P10 of the readout line RX may be formed from the same source/drain layer, or may be formed from different source/drain layers.

The second portion P2 of the data line DL and the second portion P20 of the readout line RX that overlap the non-display area NDA in the first area NBA1 may be formed from one of the first gate layer, the second gate layer, and the third gate layer described with reference to FIGS. 6 and 7. The second portion P2 of the data line DL is connected with the first portion P1 through a contact hole CH, and the second portion P20 of the readout line RX is connected with the first portion P10 through a contact hole CH. An insulating layer that the contact holes CH penetrate may vary depending on the stacked positions of the first portions P1 and P10 and the stacked positions of the second portions P2 and P20. Although the contact holes CH are illustrated as being located at the boundaries between the adjacent areas, the contact holes CH may be located in one of the adjacent areas. The contact holes CH may not be located in the bending area BA.

The third portion P3 of the data line DL and the third portion P30 of the readout line RX that overlap the bending area BA may be formed from one of the first source/drain layer, the second source/drain layer, and the third source/drain layer described with reference to FIGS. 6 and 7. The third portion P3 of the data line DL and the third portion P30 of the readout line RX are spaced far apart from the base layer SUB (refer to FIG. 6) such that tensile stress is applied to the third portion P3 and the third portion P30 during bending. The fourth portion P4 of the data line DL and the fourth portion P40 of the readout line RX that overlap the second area NBA2 may be formed from one of the first gate layer, the second gate layer, and the third gate layer described with reference to FIGS. 6 and 7. Among the second portions P2 and P20, the third portions P3 and P30, and the fourth portions P4 and P40, adjacent portions are connected through a contact hole CH. The fourth portion P4 of the data line DL is connected to a first pad electrode PD1 through a contact hole CH, and the fourth portion P40 of the readout line RX is connected to a second pad electrode PD2 through a contact hole CH.

As illustrated in FIG. 11A, in the first area A-1 of the non-display area NDA, the first to fourth data lines DL-1, DL-2, DL-3, and DL-4 and the first and second readout lines RX-1 and RX-2 may be formed from one of the second gate layer GL2 and the third gate layer GL3. Among the first to fourth data lines DL-1, DL-2, DL-3, and DL-4 and the first and second readout lines RX-1 and RX-2, adjacent signal lines may be located on different layers. According to some embodiments, the first and third data lines DL-1 and DL-3 and the first readout line RX-1 may be formed from the second gate layer GL2, and the second and fourth data lines DL-2 and DL-4 and the second readout line RX-2 may be formed from the third gate layer GL3.

Among the first to fourth data lines DL-1, DL-2, DL-3, and DL-4 and the first and second readout lines RX-1 and RX-2, adjacent signal lines are spaced apart from each other. Coupling between the adjacent signal lines may be relatively reduced.

As illustrated in FIG. 11B, in the second area B-1 of the non-display area NDA, the first to fourth data lines DL-1, DL-2, DL-3, and DL-4 and the first and second readout lines RX-1 and RX-2 may be formed from one of the first source/drain layer, the second source/drain layer, and the third source/drain layer. According to some embodiments, each of the first to fourth data lines DL-1, DL-2, DL-3, and DL-4 and the first and second readout lines RX-1 and RX-2 may be formed from the third source/drain layer SDL3.

As illustrated in FIG. 11C, in the third area C-1 of the non-display area NDA, the first to fourth data lines DL-1, DL-2, DL-3, and DL-4 and the first and second readout lines RX-1 and RX-2 may be formed from one of the second gate layer GL2 and the third gate layer GL3. Among the first to fourth data lines DL-1, DL-2, DL-3, and DL-4 and the first and second readout lines RX-1 and RX-2, adjacent signal lines are located on different layers. According to some embodiments, the first and third data lines DL-1 and DL-3 and the first readout line RX-1 may be formed from the third gate layer GL3, and the second and fourth data lines DL-2 and DL-4 and the second readout line RX-2 may be formed from the second gate layer GL2.

As described with reference to FIGS. 11A and 11C, the first to fourth data lines DL-1, DL-2, DL-3, and DL-4 and the first and second readout lines RX-1 and RX-2 include portions located on the same layer. As described with reference to FIGS. 11A and 11C, each of the first to fourth data lines DL-1, DL-2, DL-3, and DL-4 and the first and second readout lines RX-1 and RX-2 may include a portion formed from the second gate layer GL2 and a portion formed from the third gate layer GL3, and thus a difference in resistance between the signal lines may be relatively reduced. This is because signal lines located on different layers may have different line resistances due to processing issues.

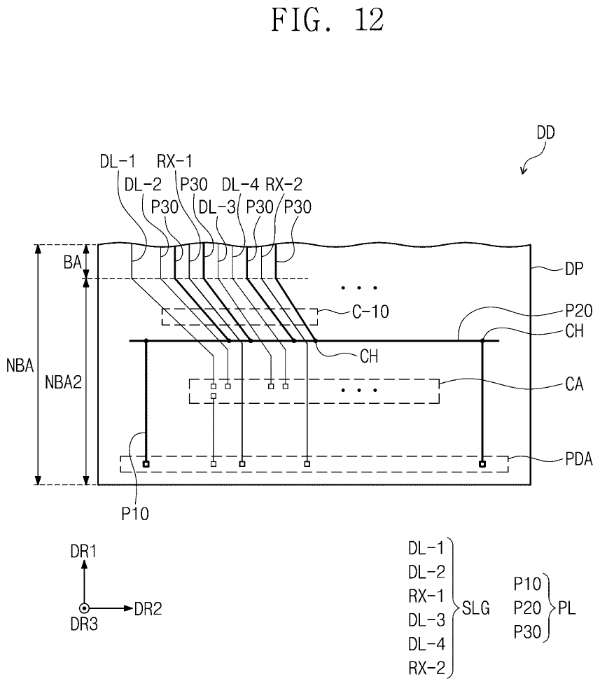

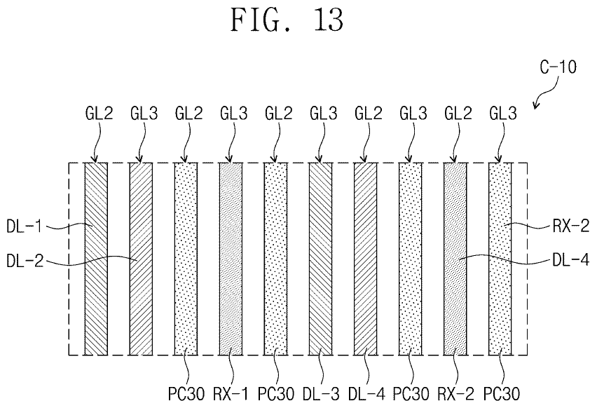

FIG. 12 is an enlarged plan view illustrating the non-display area NDA of the display device DD according to some embodiments of the present disclosure. FIG. 13 is an enlarged plan view illustrating a third area C-10 of the non-display area NDA in FIG. 12. FIG. 12 corresponds to the second area NBA2 of FIG. 9, and FIG. 13 corresponds to the third area C-1 of FIG. 11C.

The display panel DP may further include a power line PL that is electrically connected to the unit area RPU (refer to FIG. 9) and that receives a driving voltage. The power line PL may receive the second driving voltage ELVSS (refer to FIG. 4).

The power line PL extends from the pad area PDA to the display area DA (refer to FIG. 9). The power line PL does not overlap the chip area CA, and in a partial area of the non-display area, the power line PL does not overlap the first and second readout lines RX-1 and RX-2 and the first to fourth data lines DL-1, DL-2, DL-3, and DL-4.

The power line PL may include a plurality of portions distinguished from one another. The plurality of portions may be located on different layers and may be connected through contact holes CH. According to some embodiments, the power line PL may include a first portion P10, a second portion P20, and a third portion P30. The numbers of first portions P10, second portions P20, and third portions P30 illustrated in FIG. 12 are merely illustrative and are not particularly limited.

Two first portions P10 extend from the pad area PDA in the first direction DR1. The chip area CA is located between the two first portions P10 in the second direction DR2. The two first portions P10 may be connected to the second portion P20 extending in the second direction DR2. The second portion P20 may be located closer to the display area DA than the chip area CA.

The second portion P20 overlaps the first and second readout lines RX-1 and RX-2 and the first to fourth data lines DL-1, DL-2, DL-3, and DL-4. Accordingly, the second portion P20 is located on a layer different from the layers on which the first and second readout lines RX-1 and RX-2 and the first to fourth data lines DL-1, DL-2, DL-3, and DL-4 are located. When the first and second readout lines RX-1 and RX-2 and the first to fourth data lines DL-1, DL-2, DL-3, and DL-4 are formed from the second gate layer and/or the third gate layer, the second portion P20 may be formed from the first gate layer.

The third portions P30 are connected to the second portion P20 and extend in the first direction DR1. The third portions P30 may extend toward the display area DA and may overlap the display area DA. Each of the third portions P30 is located between a corresponding readout line among the first and second readout lines RX-1 and RX-2 and a corresponding data line among the first to fourth data lines DL-1, DL-2, DL-3, and DL-4 in the second direction DR2. The third portion P30 located between the corresponding readout line and the corresponding data line may suppress coupling between the corresponding readout line and the corresponding data line. Accordingly, noise in the readout line that is caused by the data line may be relatively reduced.

Referring to FIGS. 12 and 13, the first data line DL-1, the second data line DL-2, the third portion P30, the first readout line RX-1, the third portion P30, the third data line DL-3, the fourth data line DL-4, the third portion P30, the second readout line RX-2, and the third portion P30 may be sequentially arranged in an area closer to the display area DA than the second portion P20 so as not to overlap one another. Adjacent signal lines among the above-described signal lines may be located on different layers.

As illustrated in FIG. 13, in the third area C-10 of the non-display area NDA, the first to fourth data lines DL-1, DL-2, DL-3, and DL-4, the first and second readout lines RX-1 and RX-2, and the third portions P30 may be formed from one of the second gate layer GL2 and the third gate layer GL3. Among the first to fourth data lines DL-1, DL-2, DL-3, and DL-4, the first and second readout lines RX-1 and RX-2, and the third portions P30, adjacent signal lines are located on different layers. According to some embodiments, the first data line DL-1, the first-third portion P30, the second-third portion P30, the fourth data line DL-4, and the second readout line RX-2 may be formed from the second gate layer GL2, and the second data line DL-2, the first readout line RX-1, the third data line DL-3, the third-third portion P30, and the fourth-third portion P30 may be formed from the third gate layer GL3.

According to the embodiments of the present disclosure, the light sensing elements may be arranged throughout the display area. Even though the readout lines and the data lines are located on the same layer, there are no restrictions on the arrangement of the light sensing elements because the readout lines and the data lines do not cross each other.

Because the power line is located between the readout line and the data line, coupling between the readout line and the data line may be relatively reduced. Accordingly, noise in the readout line that is caused by the data line may be relatively reduced.

While aspects of some embodiments of the present disclosure have been described with reference to embodiments thereof, it will be apparent to those of ordinary skill in the art that various changes and modifications may be made thereto without departing from the spirit and scope of embodiments according to the present disclosure as set forth in the following claims, and their equivalents.

What is claimed is:

1. A display device comprising:
a base layer including a display area and a non-display area, wherein the display area includes a plurality of unit areas arranged in a first direction, and the non-display area includes a chip area and a pad area farther away from the display area in a second direction crossing the first direction than the chip area;
a driver IC in the chip area;
a pixel corresponding to each of the plurality of unit areas;
an optical sensor corresponding to each of the plurality of unit areas; and
signal line groups corresponding to the plurality of unit areas, respectively, and arranged in the first direction,
wherein each of the signal line groups includes:
a data line extending from the chip area to the display area in the second direction and electrically connect the pixel to the driver IC; and
a readout line extending from the pad area to the display area in the second direction and overlapping the chip area and electrically connected to the optical sensor, and
wherein the data line and the readout line do not overlap each other in the non-display area.

2. The display device of claim 1, wherein the plurality of unit areas define a unit row, and
wherein among the unit areas in the unit row, a first unit area is at one end of the display area in the first direction, and a last unit area is at an opposite end of the display area in the first direction.

3. The display device of claim 1, wherein the data line and the readout line are on a same layer in the non-display area.

4. The display device of claim 1, wherein each of the data line and the readout line includes a first portion and a second portion on a layer different from a layer on which the first portion is located.

5. The display device of claim 1, wherein the pixel includes a first pixel and a second pixel configured to generate light of different colors,
wherein the data line includes a first data line electrically connected to the first pixel and a second data line electrically connected to the second pixel, and
wherein in a partial area of the non-display area located between the chip area and the display area, the first data line, the second data line, and the readout line are continuously arranged in the first direction, the first data line and the readout line are on a first insulating layer, and the second data line is on a second insulating layer different from the first insulating layer.

6. The display device of claim 1, wherein the pixel includes a first pixel, a second pixel, a third pixel, and a fourth pixel,
wherein the optical sensor includes a first optical sensor and a second optical sensor,
wherein the data line includes a first data line electrically connected to the first pixel, a second data line electrically connected to the second pixel, a third data line electrically connected to the third pixel, and a fourth data line electrically connected to the fourth pixel,
wherein the readout line includes a first readout line electrically connected to the first optical sensor and a second readout line electrically connected to the second optical sensor, and
wherein in a partial area of the non-display area located between the chip area and the display area, the first data line, the second data line, and the first readout line are continuously arranged in the first direction, the first data line and the first readout line are on a first insulating layer, and the second data line is on a second insulating layer different from the first insulating layer.

7. The display device of claim 6, wherein in the partial area of the non-display area, the third data line, the fourth data line, and the second readout line are continuously arranged in the first direction from the second data line, the third data line and the second readout line are on the second insulating layer, and the fourth data line is on the first insulating layer.

8. The display device of claim 6, wherein the pixel includes a dummy electrode, a first transistor, a second transistor, and a light emitting element electrically connected to at least one of the first transistor or the second transistor,
wherein the first transistor includes a silicon semiconductor layer and a first gate electrode over the silicon semiconductor layer,
wherein the second transistor includes an oxide semiconductor layer above the first gate electrode and a second gate electrode over the oxide semiconductor layer,
wherein the dummy electrode is between the first gate electrode and the second gate electrode, and
wherein in the partial area of the non-display area, the first data line and the first readout line are on a same layer as one of the first gate electrode, the dummy electrode, and the second gate electrode.

9. The display device of claim 8, wherein in the partial area of the non-display area, the second data line is on a same layer as another one of the first gate electrode, the dummy electrode, and the second gate electrode.

10. The display device of claim 1, further comprising:
a power line electrically connected to the pixel and the optical sensor and configured to receive a driving voltage,
wherein the power line does not overlap the data line and the readout line in a partial area of the non-display area located between the chip area and the display area.

11. The display device of claim 10, wherein the pixel includes a first pixel and a second pixel configured to generate light of different colors,
wherein the data line includes a first data line electrically connected to the first pixel and a second data line electrically connected to the second pixel, and
wherein in the partial area of the non-display area, the first data line, the second data line, the power line, and the readout line are continuously arranged in the first direction.

12. The display device of claim 11, wherein the first data line and the power line are on a first insulating layer, and the second data line and the readout line are on a second insulating layer different from the first insulating layer.

13. The display device of claim 11, wherein the power line includes:
at least one first portion extending from the pad area in the second direction;
a second portion connected to the at least one first portion and extending in the first direction; and
third portions connected to the second portion and extending in the second direction to overlap the display area, wherein the third portions correspond to the signal line groups, respectively.

14. The display device of claim 13, wherein the second portion is on a layer different from layers on which the first data line, the second data line, and the readout line are located.

15. An electronic device comprising:
a display device, the display device comprising:
a base layer including a display area and a non-display area around the display area;
a driver IC in the non-display area;
first to fourth pixels in the display area;
a first optical sensor and a second optical sensor in the display area;
signal lines overlapping the display area and the non-display area; and
a printed circuit board coupled to the non-display area of the base layer,
wherein the signal lines include:
first to fourth data lines configured to electrically connect the first to fourth pixels to the driver IC; and
a first readout line and a second readout line configured to electrically connect the first optical sensor and the second optical sensor to the printed circuit board,
wherein the first to fourth data lines do not overlap the first readout line and the second readout line at least in the non-display area,
wherein end portions of the first to fourth data lines overlap the driver IC, and
wherein middle portions of the first readout line and the second readout line overlap the driver IC.

16. The electronic device of claim 15, wherein in a partial area of the non-display area located between the driver IC and the display area, the first data line, the second data line, and the first readout line are continuously arranged in a first direction, the first data line and the first readout line are on a first insulating layer, and the second data line is on a second insulating layer different from the first insulating layer.

17. The electronic device of claim 16, wherein in the partial area of the non-display area, the third data line, the fourth data line, and the second readout line are continuously arranged in the first direction from the second data line, the third data line and the second readout line are on the second insulating layer, and the fourth data line is on the first insulating layer.

18. The electronic device of claim 15, further comprising:
a power line electrically connected to the first to fourth pixels, the first optical sensor, and the second optical sensor and configured to receive a driving voltage,
wherein in a partial area of the non-display area located between the driver IC and the display area, the power line is between a corresponding one of the first to fourth data lines and a corresponding one of the first readout line and the second readout line.

19. The electronic device of claim 18, wherein among the first to fourth data lines, the first readout line, and the second readout line, adjacent signal lines are on different layers in the partial area of the non-display area.

20. An electronic device comprising:
a display device, the display device comprising:
a base layer including a display area in which a plurality of pixels and a plurality of optical sensors are located and a non-display area around the display area;
a driver IC in the non-display area;
a printed circuit board coupled to the non-display area of the base layer;
a first signal line extending from an area overlapping the driver IC to the display area and electrically connect the driver IC and a first pixel among the plurality of pixels; and
a second signal line extending from an area overlapping the printed circuit board to the display area through an area overlapping the driver IC, wherein the second signal line electrically connects the printed circuit board and a first optical sensor among the plurality of optical sensors,
wherein among the plurality of pixels and the plurality of optical sensors, the first pixel and the first optical sensor are closest to each other, and
wherein another signal line extending in a direction parallel to the first signal line or the second signal line is not between the first signal line and the second signal line.
